(19) United States
(12) Patent Application Publication
(10) Pub. No.: US 2024/0096686 A1
(43) Pub. Date: Mar. 21, 2024

(54) FOCUS RING, APPARATUS AND METHOD FOR PROCESSING SEMICONDUCTOR WAFER

(71) Applicant: Hon Young Semiconductor Corporation, Hsinchu City (TW)

(72) Inventors: Chia-Jen CHANG, Hsinchu City (TW); Hsin-Chung HO, Hsinchu City (TW)

(21) Appl. No.: 18/169,225

(22) Filed: Feb. 15, 2023

(30) Foreign Application Priority Data
Sep. 16, 2022 (TW) 111135116

(51) Int. Cl. H01L 21/687; H01J 37/32

(52) U.S. Cl. CPC H01L 21/68721; H01J 37/32642; H01L 21/68735; H01L 21/68757; H01L 21/68785; H01J 2237/334

(57) ABSTRACT

A focus has an opening and an upper surface surrounding the opening. The opening is configured to accommodate a SiC wafer. The SiC wafer has a first surface and a second surface opposite to the first surface. When the focus ring is mounted in a semiconductor wafer processing apparatus and the SiC wafer is positioned in the opening of the focus ring, the upper surface of the focus ring is lower than the first surface of the SiC wafer and is higher than the second surface of the SiC wafer.

### RELATED APPLICATIONS

This application claims priority to Taiwan Application Serial Number 111135116, filed Sep. 16, 2022, the disclosure of which is incorporated herein by reference in its entirety.

### BACKGROUND

### Technical Field

The present disclosure relates to a focus ring, a method for processing a semiconductor wafer and a semiconductor wafer processing apparatus.

### Description of Related Art

When a semiconductor wafer is processed by wafer processing equipment, if the dimensions of the wafer do not match those of the equipment, the equipment could crash and the wafer could be damaged.

### SUMMARY

In view of the foregoing, one of the objects of the present disclosure is to provide a focus ring, a wafer processing method and a wafer processing apparatus for the processing of SiC wafers.

To achieve the objective stated above, in accordance with an embodiment of the present disclosure, a focus has an opening and an upper surface surrounding the opening. The opening is configured to accommodate a SiC wafer. The SiC wafer has a first surface and a second surface opposite to the first surface. When the focus ring is mounted in a semiconductor wafer processing apparatus and the SiC wafer is positioned in the opening of the focus ring, the upper surface of the focus ring is lower than the first surface of the SiC wafer and is higher than the second surface of the SiC wafer.

In one or more embodiments of the present disclosure, the semiconductor wafer processing apparatus is a plasma etching apparatus, and the focus ring is configured to be fit over a lower electrode of the plasma etching apparatus.

In one or more embodiments of the present disclosure, when the focus ring is mounted in the semiconductor wafer processing apparatus and the SiC wafer is positioned in the opening of the focus ring, a height difference between the upper surface of the focus ring and the first surface of the SiC wafer is at least 0.17 mm.

In one or more embodiments of the present disclosure, the focus ring comprises a ceramic material.

In accordance with an embodiment of the present disclosure, a method for processing a semiconductor wafer includes: providing a focus ring for a Si wafer; machining the focus ring to decrease a height of the focus ring; mounting the focus ring in a semiconductor wafer processing apparatus and positioning a SiC wafer in an opening of the focus ring; pressing a surface of the SiC wafer with a clamping mechanism, the surface of the SiC wafer being above the focus ring; and processing the SiC wafer.

In one or more embodiments of the present disclosure, the step of machining the focus ring includes: removing a portion of the focus ring by means of grinding, turning or sandblasting to decrease the height of the focus ring.

In one or more embodiments of the present disclosure, the step of removing a portion of the focus ring includes: performing grinding, turning or sandblasting against an upper surface of the focus ring.

In one or more embodiments of the present disclosure, the method further includes: after processing of the SiC wafer is completed, removing the SiC wafer from the opening of the focus ring; positioning the Si wafer in the opening of the focus ring; pressing a surface of the Si wafer with the clamping mechanism, the surface of the Si wafer being above the focus ring; and processing the Si wafer.

In one or more embodiments of the present disclosure, the semiconductor wafer processing apparatus is a plasma etching apparatus, and the step of mounting the focus ring in the semiconductor wafer processing apparatus includes: fitting the focus ring over a lower electrode of the plasma etching apparatus.

In one or more embodiments of the present disclosure, when the SiC wafer is positioned in the opening of the focus ring, the focus ring is lower than the SiC wafer by at least 0.17 mm.

In accordance with an embodiment of the present disclosure, a semiconductor wafer processing apparatus includes a focus ring and a clamping mechanism. The focus ring has an opening and an upper surface surrounding the opening. The opening being configured to accommodate a SiC wafer. The SiC wafer has a first surface and a second surface opposite to the first surface. When the SiC wafer is positioned in the opening of the focus ring, the upper surface of the focus ring is lower than the first surface of the SiC wafer and is higher than the second surface of the SiC wafer. The clamping mechanism is movably disposed over the focus ring and configured to press the first surface of the SiC wafer.

In one or more embodiments of the present disclosure, the semiconductor wafer processing apparatus is a plasma etching apparatus. The plasma etching apparatus further includes a lower electrode. The focus ring is fit over the lower electrode.

In one or more embodiments of the present disclosure, the plasma etching apparatus further includes a supply source of a thermally conductive medium. The supply source is configured to supply the thermally conductive medium to a gap between the lower electrode and the SiC wafer.

In one or more embodiments of the present disclosure, the opening of the focus ring is further configured to accommodate a Si wafer. The Si wafer has a first surface and a second surface. The second surface of the Si wafer is opposite to the first surface of the Si wafer. When the Si wafer is positioned in the opening of the focus ring, the upper surface of the focus ring is lower than the first surface of the Si wafer and is higher than the second surface of the Si wafer. The clamping mechanism is further configured to press the first surface of the Si wafer.

In sum, the semiconductor wafer processing apparatus of the present disclosure is based on a wafer processing apparatus designed for Si wafers and has the height of its focus ring modified, making the focus ring compatible with the relatively thinner SiC wafers. The modified focus ring is not only eligible for SiC wafer processing, but also remains qualified for Si wafer processing.

### BRIEF DESCRIPTION OF THE DRAWINGS

To make the objectives, features, advantages, and embodiments of the present disclosure, including those mentioned above and others, more comprehensible, descriptions of the accompanying drawings are provided as follows.

FIG. 1 illustrates a schematic side view of a semiconductor wafer processing apparatus in accordance with an embodiment of the present disclosure, in which the semiconductor wafer processing apparatus is processing a SiC wafer;

FIG. 2 illustrates a schematic top view of the focus ring of the semiconductor wafer processing apparatus shown in FIG. 1; and

FIG. 3 illustrates a schematic side view of the semiconductor wafer processing apparatus of FIG. 1 processing a Si wafer.

### DETAILED DESCRIPTION

For the completeness of the description of the present disclosure, reference is made to the accompanying drawings and the various embodiments described below. Various features in the drawings are not drawn to scale and are provided for illustration purposes only. To provide full understanding of the present disclosure, various practical details will be explained in the following descriptions. However, a person with an ordinary skill in relevant art should realize that the present disclosure can be implemented without one or more of the practical details. Therefore, the present disclosure is not to be limited by these details.

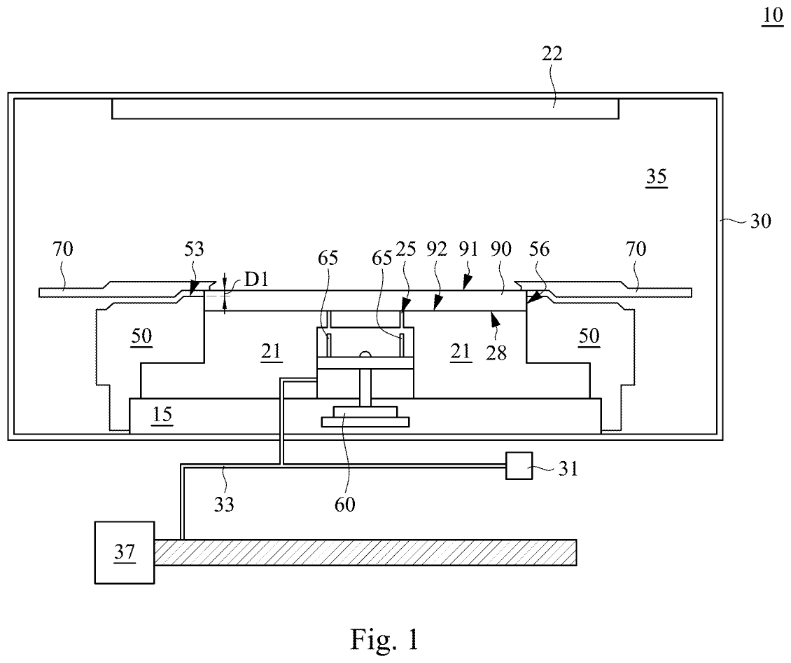

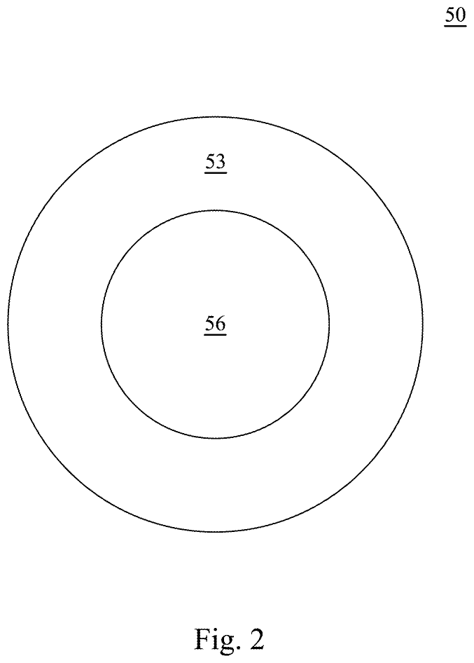

Reference is made to FIGS. 1 and 2. FIG. 1 illustrates a schematic side view of a semiconductor wafer processing apparatus 10 in accordance with an embodiment of the present disclosure, in which the semiconductor wafer processing apparatus 10 is processing a silicon carbide (SiC) wafer 90. FIG. 2 illustrates a schematic top view of the focus ring 50 of the semiconductor wafer processing apparatus 10 shown in FIG. 1. The semiconductor wafer processing apparatus 10 includes a focus ring 50 for positioning a wafer 90. Specifically, the focus ring 50 has an opening 56 at its center, and the opening 56 is configured to accommodate the wafer 90. In some embodiments, the focus ring 50 can include a ceramic material.

As shown in FIG. 1, the semiconductor wafer processing apparatus 10 further includes a base 15. The focus ring 50 is disposed on the base 15. The semiconductor wafer processing apparatus 10 further includes a clamping mechanism 70. The clamping mechanism 70 is movably disposed over the focus ring 50 and is configured to press the wafer 90 positioned in the opening 56 of the focus ring 50, so as to hold the wafer 90 in position.

As shown in FIG. 1, specifically, the wafer 90 has a first surface 91 and a second surface 92. The first surface 91 is away from the base 15. The second surface 92 is opposite to the first surface 91. Before the semiconductor wafer processing apparatus 10 starts to process the wafer 90, the clamping mechanism 70 can move towards the focus ring 50 (i.e., the clamping mechanism 70 moves downwards) and press the first surface 91 of the wafer 90 to hold the wafer 90 in the opening 56 of the focus ring 50. After the semiconductor wafer processing apparatus 10 finishes processing the wafer 90, the clamping mechanism 70 can move away from the focus ring 50 (i.e., the clamping mechanism 70 moves upwards) and separate with the first surface 91 of the wafer 90 to allow the wafer 90 to be removed from the opening 56 of the focus ring 50. In some embodiments, the clamping mechanism 70 is ring-shaped and is configured to abut against a peripheral portion of the wafer 90 (i.e., the portion of the wafer 90 in proximity to its outer periphery).

As shown in FIG. 1, in the illustrated embodiment, the semiconductor wafer processing apparatus 10 is a plasma etching apparatus. The plasma etching apparatus further includes a housing 30, a lower electrode 21 and an upper electrode 22. The housing 30 has a chamber 35. The base 15, the focus ring 50 and the clamping mechanism 70 are disposed in the housing 30. The lower electrode 21 and the upper electrode 22 are disposed in the housing 30 and are spaced apart from each other. The lower electrode 21 is disposed on the base 15. The focus ring 50 is fit over the lower electrode 21 and encircles a supporting surface 28 of the lower electrode 21 (i.e., the surface of the lower electrode 21 for supporting the wafer 90). An upper surface 53 of the focus ring 50 (i.e., the surface of the focus ring 50 that is away from the base 15 and surrounds the opening 56) is above the supporting surface 28 of the lower electrode 21.

Continuing from the previous paragraph, the lower electrode 21 can be connected to a radio frequency (RF) power supply (not depicted). The RF power supply is configured to supply RF power to the lower electrode 21, such that a processing gas (which can be injected into the chamber 35 of the housing 30 by a processing gas supply source (not depicted)) between the lower electrode 21 and the upper electrode 22 is excited and produces plasma. As a result, plasma processing of the wafer 90 can be realized.

Since using RF power would produce a lot of heat, in some embodiments, as shown in FIG. 1, the semiconductor wafer processing apparatus 10 further includes a supply source 31 of a thermally conductive medium and a pipeline 33 connected to the supply source 31. The supply source 31 is configured to supply the thermally conductive medium (fluid medium, such as helium) to a gap between the second surface 92 of the wafer 90 and the supporting surface 28 of the lower electrode 21 via the pipeline 33 and one or more through holes 25 of the lower electrode 21, so as to control the temperatures of the lower electrode 21 and the wafer 90. It is noted that the gap is generally very thin compared to the wafer 90 and the lower electrode 21 and is thus not directly visible in FIG. 1.

As shown in FIG. 1, in some embodiments, the semiconductor wafer processing apparatus 10 further includes a pump 37. The pump 37 is connected to the pipeline 33 and is configured to drive the thermally conductive medium to flow from the supply source 31 to the gap between the second surface 92 of the wafer 90 and the supporting surface 28 of the lower electrode 21 via the pipeline 33 and the through holes 25 of the lower electrode 21. In some embodiments, in addition to driving the thermally conductive medium, the pump 37 can also be used to create vacuum in the chamber 35 of the housing 30.

During the processing of the wafer 90 by the semiconductor wafer processing apparatus 10, the clamping mechanism 70 being arranged to press the first surface 91 of the wafer 90 can prevent an excessive amount of thermally conductive medium from being injected into the gap between the second surface 92 of the wafer 90 and the supporting surface 28 of the lower electrode 21 and making the wafer 90 “float”, which could lead to non-uniform surface temperature of the wafer 90 and causing a defect in the wafer 90.

Continuing from the previous paragraph, to ensure that the clamping mechanism 70 can press the first surface 91 of the wafer 90, the focus ring 50 must be lower than the wafer 90. Specifically, when the wafer 90 is positioned in the opening 56 of the focus ring 50, the upper surface 53 of the focus ring 50 is required to be below the first surface 91 of the wafer 90 to allow the clamping mechanism 70 to press the wafer 90. If the upper surface 53 of the focus ring 50 is above the first surface 91 of the wafer 90, then the clamping mechanism 70 would be blocked by the focus ring 50 and unable to move further downward to press the first surface 91 of the wafer 90. In this case, an excessive amount of thermally conductive medium will be injected into the gap between the wafer 90 and the lower electrode 21, making the wafer 90 “float” and causing damage to the wafer 90.

Common materials for wafers include silicon (Si) and silicon carbide (SiC). A Si wafer is typically thicker than a SiC wafer. Wafer processing apparatuses that are designed for Si wafers and are currently widely used in the industry include taller focus rings. If a SiC wafer is placed into a focus ring of a wafer processing apparatus designed for Si wafers, the top surface of the SiC wafer would be lower than the upper surface of the focus ring. As a result, the clamping mechanism 70 would not be able to press the SiC wafer, and the aforementioned “wafer floating” problem would arise, or the apparatus might crash. Accordingly, the wafer processing apparatuses that are designed for Si wafers and are currently widely used in the industry cannot be used to perform SiC wafer processing directly.

In view of said issue, the semiconductor wafer processing apparatus 10 of the present disclosure is based on a wafer processing apparatus designed for Si wafers, and the focus ring, which is originally only compatible with Si wafers, has its height modified, such that the upper surface 53 of the modified focus ring 50 is lower than the first surface 91 of the SiC wafer 90 and is higher than the second surface 92 of the SiC wafer 90 (when the SiC wafer 90 is positioned in the opening 56 of the focus ring 50). By this arrangement, both the semiconductor wafer processing apparatus 10 and the focus ring 50 would be compatible with the SiC wafer 90, in other words, when the SiC wafer 90 is positioned in the opening 56 of the focus ring 50, the clamping mechanism 70 can successfully press the SiC wafer 90 to facilitate subsequent processing of the SiC wafer 90. In the case of plasma etching apparatus, using the modified focus ring 50 with decreased height can prevent the aforementioned “wafer floating” problem and thus prevent damage to the SiC wafer 90.

Modification of the focus ring 50 can be done by precision machining. In some embodiments, modification/machining of the focus ring 50 can include removing a portion of the focus ring 50 by means of grinding, turning or sandblasting to decrease the height of the focus ring 50. After the machining step is completed, the focus ring 50 can be mounted in the semiconductor wafer processing apparatus 10 for use (e.g., the focus ring 50 can be fit over the lower electrode 21). In some embodiments, the height of the focus ring 50 can be decreased by performing grinding, turning or sandblasting against the upper surface 53 of the focus ring 50.

As shown in FIG. 1, in some embodiments, in order to effectively prevent the aforementioned “wafer floating” problem, when the focus ring 50 is mounted in the semiconductor wafer processing apparatus 10 and the SiC wafer 90 is positioned in the opening 56 of the focus ring 50, the focus ring 50 is lower than the SiC wafer 90 by at least 0.17 mm. In other words, a height difference D1 between the upper surface 53 of the focus ring 50 and the first surface 91 of the SiC wafer 90 is at least 0.17 mm. By this arrangement, when the thermally conductive medium is injected into the gap between the second surface 92 of the wafer 90 and the supporting surface 28 of the lower electrode 21, the flow rate of the thermally conductive medium can be controlled to stay under the specified value of 20 sccm (when the pressure of the thermally conductive medium is 10 Torr).

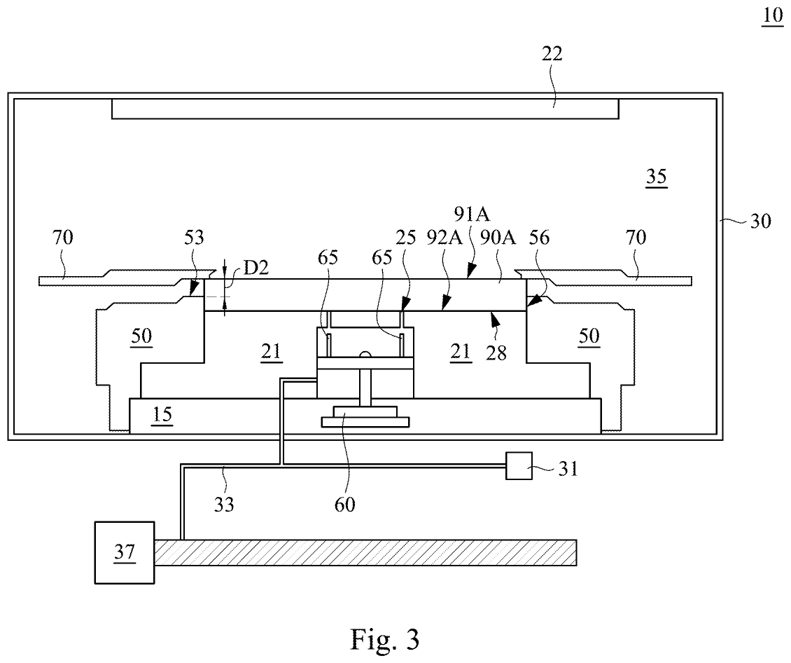

The modified focus ring 50 is compatible not only with the SiC wafer 90, but also with the Si wafer 90A (see FIG. 3) of greater thickness than the SiC wafer 90. As a result, the processing of the SiC wafer 90 and the Si wafer 90A can be carried out by a single semiconductor wafer processing apparatus 10.

As shown in FIG. 1, to process the SiC wafer 90, the SiC wafer 90 is first placed in the opening 56 of the focus ring 50, and then the clamping mechanism 70 presses the first surface 91 of the SiC wafer 90, which is above the focus ring 50, and the processing of the SiC wafer 90 can begin thereafter. Using plasma etching as example, during the processing of the wafer, the RF power supply supplies RF power to the lower electrode 21 to generate plasma, and in the meantime, the supply source 31 supplies the thermally conductive medium to the gap between the SiC wafer 90 and the lower electrode 21 to control the temperatures of the SiC wafer 90 and the lower electrode 21. After the processing of the SiC wafer 90 is completed, the SiC wafer 90 can be removed from the opening 56 of the focus ring 50.

Reference is made to FIG. 3. After the processed SiC wafer 90 is removed, the Si wafer 90A can be placed in the opening 56 of the focus ring 50, and then the clamping mechanism 70 presses the first surface 91A of the Si wafer 90A (since the Si wafer 90A has a thickness greater than the thickness of the SiC wafer 90, the focus ring 50 is also lower than the first surface 91A of the Si wafer 90A), and the processing of the Si wafer 90A can begin thereafter.

After the Si wafer 90A is placed in the opening 56 of the focus ring 50, a height difference D2 between the focus ring 50 and the Si wafer 90A is greater than the height difference D1 between the focus ring 50 and the SiC wafer 90. Nonetheless, it does not affect the clamping mechanism's ability to press the Si wafer 90A. The flow rate of the thermally conductive medium that flows into the gap between the second surface 92A of the Si wafer 90A and the supporting surface 28 of the lower electrode 21 can still be controlled effectively to prevent damage to the Si wafer 90A.

As shown in FIG. 3, in some embodiments, the semiconductor wafer processing apparatus 10 further includes a vertical motion mechanism 60 (e.g., a pneumatic cylinder) and one or more posts 65. The posts 65 are connected to the vertical motion mechanism 60 and are configured to move the wafer (the SiC wafer 90 or the Si wafer 90A) into or out of the opening 56 of the focus ring 50.

Specifically, before wafer processing begins, the posts 65 are driven by the vertical motion mechanism 60 to pass through the through holes 25 of the lower electrode 21 and rise above the supporting surface 28 of the lower electrode 21. The semiconductor wafer processing apparatus 10 can utilize a robotic arm or other displacement mechanism to move the wafer to the upper side of the opening 56 of the focus ring 50 and place the wafer on the posts 65. Subsequently, the vertical motion mechanism 60 can drive the posts 65 to move downward, such that the wafer falls into the opening 56 of the focus ring 50 and lies on the supporting surface 28 of the lower electrode 21. After wafer processing is completed, the vertical motion mechanism 60 can drive the posts 65 to move upward to push the wafer up and remove the wafer from the opening 56 of the focus ring 50.

In sum, the semiconductor wafer processing apparatus of the present disclosure is based on a wafer processing apparatus designed for Si wafers and has the height of its focus ring modified, making the focus ring compatible with the relatively thinner SiC wafers. The modified focus ring is not only eligible for SiC wafer processing, but also remains qualified for Si wafer processing.

Although the present disclosure has been described by way of the exemplary embodiments above, the present disclosure is not to be limited to those embodiments. Any person skilled in the art can make various changes and modifications without departing from the spirit and the scope of the present disclosure. Therefore, the protective scope of the present disclosure shall be the scope of the claims as attached.

What is claimed is:

1. A focus ring having an opening and an upper surface surrounding the opening, the opening being configured to accommodate a SiC wafer, wherein the SiC wafer has a first surface and a second surface opposite to the first surface, when the focus ring is mounted in a semiconductor wafer processing apparatus and the SiC wafer is positioned in the opening of the focus ring, the upper surface of the focus ring is lower than the first surface of the SiC wafer and is higher than the second surface of the SiC wafer.

2. The focus ring of claim 1, wherein the semiconductor wafer processing apparatus is a plasma etching apparatus, and the focus ring is configured to be fit over a lower electrode of the plasma etching apparatus.

3. The focus ring of claim 1, wherein when the focus ring is mounted in the semiconductor wafer processing apparatus and the SiC wafer is positioned in the opening of the focus ring, a height difference between the upper surface of the focus ring and the first surface of the SiC wafer is at least 0.17 mm.

4. The focus ring of claim 1, wherein the focus ring comprises a ceramic material.

5. A method for processing a semiconductor wafer, comprising:
providing a focus ring for a Si wafer;
machining the focus ring to decrease a height of the focus ring;
mounting the focus ring in a semiconductor wafer processing apparatus and positioning a SiC wafer in an opening of the focus ring;
pressing a surface of the SiC wafer with a clamping mechanism, the surface of the SiC wafer being above the focus ring; and
processing the SiC wafer.

6. The method of claim 5, wherein the step of machining the focus ring comprises: removing a portion of the focus ring by means of grinding to decrease the height of the focus ring.

7. The method of claim 6, wherein the step of removing a portion of the focus ring comprises: performing grinding against an upper surface of the focus ring.

8. The method of claim 5, wherein the step of machining the focus ring comprises: removing a portion of the focus ring by means of turning to decrease the height of the focus ring.

9. The method of claim 8, wherein the step of removing a portion of the focus ring comprises: performing turning against an upper surface of the focus ring.

10. The method of claim 5, wherein the step of machining the focus ring comprises: removing a portion of the focus ring by means of sandblasting to decrease the height of the focus ring.

11. The method of claim 10, wherein the step of removing a portion of the focus ring comprises: performing sandblasting against an upper surface of the focus ring.

12. The method of claim 5, further comprising:
after processing of the SiC wafer is completed, removing the SiC wafer from the opening of the focus ring;
positioning the Si wafer in the opening of the focus ring;
pressing a surface of the Si wafer with the clamping mechanism, the surface of the Si wafer being above the focus ring; and
processing the Si wafer.

13. The method of claim 5, wherein the semiconductor wafer processing apparatus is a plasma etching apparatus, and the step of mounting the focus ring in the semiconductor wafer processing apparatus comprises: fitting the focus ring over a lower electrode of the plasma etching apparatus.

14. The method of claim 5, wherein when the SiC wafer is positioned in the opening of the focus ring, the focus ring is lower than the SiC wafer by at least 0.17 mm.

15. A semiconductor wafer processing apparatus, comprising:
a focus ring having an opening and an upper surface surrounding the opening, the opening being configured to accommodate a SiC wafer, wherein the SiC wafer has a first surface and a second surface opposite to the first surface, when the SiC wafer is positioned in the opening of the focus ring, the upper surface of the focus ring is lower than the first surface of the SiC wafer and is higher than the second surface of the SiC wafer; and
a clamping mechanism movably disposed over the focus ring and configured to press the first surface of the SiC wafer.

16. The semiconductor wafer processing apparatus of claim 15, wherein the semiconductor wafer processing apparatus is a plasma etching apparatus, the plasma etching apparatus further comprises a lower electrode, and the focus ring is fit over the lower electrode.

17. The semiconductor wafer processing apparatus of claim 16, wherein the plasma etching apparatus further comprises a supply source of a thermally conductive medium, the supply source is configured to supply the thermally conductive medium to a gap between the lower electrode and the SiC wafer.

18. The semiconductor wafer processing apparatus of claim 15, wherein when the SiC wafer is positioned in the opening of the focus ring, a height difference between the upper surface of the focus ring and the first surface of the SiC wafer is at least 0.17 mm.

19. The semiconductor wafer processing apparatus of claim 15, wherein the opening of the focus ring is further configured to accommodate a Si wafer, wherein the Si wafer has a first surface and a second surface, the second surface of the Si wafer is opposite to the first surface of the Si wafer, when the Si wafer is positioned in the opening of the focus ring, the upper surface of the focus ring is lower than the first surface of the Si wafer and is higher than the second surface of the Si wafer, wherein the clamping mechanism is further configured to press the first surface of the Si wafer.

20. The semiconductor wafer processing apparatus of claim 15, wherein the focus ring comprises a ceramic material.
